(19) United States
(12) Patent Application Publication
(10) Pub. No.: US 2025/0363272 A1
(43) Pub. Date: Nov. 27, 2025

(54) METHOD OF DETECTION OF HYDROCARBON HORIZONTAL SLIPPAGE PASSAGES

(71) Applicant: Abu Dhabi National Oil Company, Abu Dhabi (AE)

(72) Inventors: Abdelwahab NOUFAL, Abu Dhabi (AE); Khalid OBAID, Abu Dhabi (AE)

(73) Assignee: Abu Dhabi National Oil Company, Abu Dhabi (AE)

(21) Appl. No.: 19/289,274

(22) Filed: Aug. 4, 2025

Related U.S. Application Data
(63) Continuation-in-part of application No. 17/428,614, filed on Aug. 4, 2021, now abandoned.

(51) Int. Cl. G06F 30/28

(52) U.S. Cl. CPC G06F 30/28

(57) ABSTRACT

A method of detection of hydrocarbon horizontal slippage passages comprising the following steps: (a.) slippage passage data acquisition and identification; (b.) slippage passage prediction; (c.) slippage passage characterization; (d.) slippage passage calibration; and (e.) slippage passage parameterization and modelling. The present invention also relates to the use of such a method 1 for positioning a well bore for hydrocarbon production.

This application is a continuation-in-part of U.S. patent application Ser. No. 17/428,614, filed Aug. 4, 2021, which is a national phase of International Patent Application No. PCT/IB2019/050905, filed Feb. 5, 2019, both of which are hereby incorporated herein by reference in their entirety.

### 1. TECHNICAL FIELD

The present invention relates to a method of detection of hydrocarbon horizontal slippage passages. Such detection can be used to improve oil and gas production by locating production perforations at locations of horizontal slippage passages.

### 2. BACKGROUND OF THE INVENTION

The present invention relates to a method of detection of hydrocarbon horizontal slippage passages. Such slippage passages are naturally occurring macroscopic planar discontinuities in rock due to deformation, and/or diagenesis. Thus, such slippage passages are generally horizontally oriented in a macroscopic view. Therefore, “horizontally” should not be understood in a strict mathematical sense. Each slippage passage marks a weak plane in the rock and possess different geometry, pattern, and fluid flow property. In hydrocarbon containing rock the slippage passages allow the flow of oil and gas. Therefore, in hydrocarbon production it is intended to localize slippage passages to be able to produce oil and gas from the slippage passages. The influence of hydrocarbon production by slippage passages is described in some scientific papers and patent documents, of the present inventors.

The paper Khalid Obaid, Abdelwahab Noufal, Mohamed Mahgoub; “Twisting Slip and Rotation of UAE Fault System”, 2017, teaches of Abu Dhabi fields which are influenced by strike-slip and their damage zones as a main tectonic regime. A damage zone is defined as the deformed volume of rocks around a fault surface that results from the initiation, propagation, interaction and build-up of slip along fault segments. The damage zones thus impact the distribution of the migration pathways which in turn increase the drilling risks. It was found that slippage and rotation along the fault segments in Abu Dhabi fields increase the damage zones widths around the fault segments. The paper goes further to describe that faults and shears act as migration pathways for oil and gas.

Although, the paper is related to the influence of strike-slip fault and the corresponding damage zones on Abu Dhabi fields, that are developed due to tectonic activities, it does not disclose a method to identify slippage passages.

The paper Yasmin Abu Hiljeh, Sabah Al-Hosani, Adbelwahab Noufal “Characteristics of Fault Zones in Layered Carbonate Sequences, Onshore Abu Dhabi, UAE”, 2016, discusses the mechanical and kinematic properties and the structural architecture of fault zones and their importance in structural geometry and fluid flows rates. The paper discusses that, the increase in permeability is associated with these stressed faults. The stressed faults result from brecciation during shearing and formation of a damage zone adjacent to the faults. The change in pore-pressure in any context can have influence on slippage potential of these deformation zones and can contribute changes to the reservoir permeability tensor. The zones are thus denoted and identified by enhanced fluid flow transmissibility. Further, that these zones can have greater permeability than the host rock. The method, however, does not disclose the detection of horizontal slippage passages.

Document U.S. Pat. No. 6,266,618 B1 teaches a specific method for automatic detection of planar heterogeneities crossing the stratification of an environment from images of borehole walls or developments of core samples of said environment. The method, however, does not disclose the detection of horizontal slippage passages.

Document U.S. Pat. No. 6,819,111 B2 teaches a method for determining horizontal and vertical resistivity in an anisotropic formation using a combination of orientable triaxial an array antenna conveyed downhole. The method, however, does not disclose the detection of horizontal slippage passages.

Thus, it is an object of the invention to provide a method for the reliable and fast detection of hydrocarbon horizontal slippage passages.

### 3. Summary of the Invention

The above mentioned problem is solved by a method of detection of hydrocarbon horizontal slippage passages and a system that implements the same comprising the following steps:
a. slippage passage data acquisition and Identification (10);
b. slippage passage prediction (20);
c. slippage passage characterization (30)
d. slippage passage calibration (40).
e. slippage passage parameterization and modelling (70).

The method allows a fast and reliable preferably automatic or semi-automatic detection of hydrocarbon horizontal slippage passages and improves hydrocarbon production. In the step of slippage passage data acquisition all necessary data is acquired that is used for the detection of hydrocarbon horizontal slippage passages. In accordance with some embodiments, the data may be acquired from one or more sensors emplaced within or around wells or other hydrocarbon deposits that communicate with a backend computer system to process such data in accordance with the methods described herein.

In the step of slippage passage prediction one or more reviews for individual wells is performed based on the acquired slippage passage data. The acquired slippage passage data, preferably BHI (Borehole Image) with picking of all structural data (fractures and bedding) is used to generate a model of the reservoir main porosity contribution coming from matrix or secondary porosity.

In the step of slippage passage characterization, the performed reviews for individual wells are combined to generate field wide slipping passage characterization data. This step generates a model of the porosity and permeability contributors, which shows these are the direct contribution of slippage passages. This step has the technical effect of delineating the flow contributors in the reservoir laterally.

In the step of slippage passage parameterization and modelling the field wide slipping passage characterization data is used to generate different preferably 3-dimensional models that describe the field in terms of slipping passage parameters like slipping passage porosity, slipping passage permeability and effective slipping passage permeability.

Preferably, the step of slippage passage data acquisition and identification comprises data acquisition in stratified rock. Thus, the input data of the detection method corresponds to the different layers of the rock of interest.

Preferably, the step of slippage passage data acquisition and identification comprises acquiring borehole image data. Thus, borehole image data is used as input data for the detection method. Such borehole image data is comparably easy to produce.

Preferably step of slippage passage data acquisition and identification comprises an acquisition of one or more of
a. density data,
b. gamma ray data;
c. sonic compressional data;
d. fast sonic shear data;
e. slow sonic shear data; and
f. core data.

Further input data to the detection method can be density data, gamma ray data, sonic compressional data, fast sonic shear data, slow sonic shear data and core data. Such data can be used for creating a 1-dimensional geomechanics model of a well.

Acoustic measurements using a full-waveform, wideband-frequency sonic tool can preferably be used to evaluate the stress regime and direction using both near field flexural-shear and Stoneley waves, as well as far field P-wave reflections. Zones showing differences in the 3-shear moduli permit a quantification of stress magnitudes as a function of the principal stresses in the near wellbore region. Whereas the far-field reflections of the P-wave in all azimuths are utilized to determine the dip and azimuth of interpreted slippage passages and/or fractures extending 10's of meters away from the wellbore using 3-dimensional Slowness-Time-Coherence and ray tracing. The stress field at the wellbore scale, and in the far-field should be consistent to accurately represent the in-situ stress state.

Preferably, the step of slippage data acquisition comprises one or more of the following steps:
a. core analysis;
b. bore hole image analysis;
c. drilling data analysis;
d. dynamic data analysis;
e. seismic attribute analysis; and
f. curvature/strain analysis.

The core analysis is preferably done by describing the core structurally, collecting all the features characterizing the slippage passage, in addition to diagenesis description and provides matching the BHI with the core; structural analysis and diagnostic features.

The bore hole image analysis provides structural analysis of the slippage passages, differentiation between primary (matrix) and secondary porosity (Slippage passages, voids and fractures).

The drilling data analysis provides an analysis of data of drilling events, like lost circulation events, stuck pipes, etc., which are collected while drilling.

The seismic attribute analysis provides the best attributes describing the slippage passages.

Curvature/strain analysis provides strain maps and comparing these maps with the attributes showing slippage passages.

Suitable methods, systems, and algorithms for performing the steps of slippage data acquisition are provided in U.S. patent application Ser. No. 18/000,596 filed Dec. 2, 2022, and published as U.S. Patent Application Publication No. 2023/0332495 on Oct. 19, 2023, titled BOREHOLE IMAGE INTERPRETATION AND ANALYSIS, the entire disclosure of which is incorporated by reference herein.

Preferably the step of slippage passage prediction comprises one or more of the following steps:
a. petrophysical review;
b. determining of slippage passage potential index (SPPI);
c. azimuth, edge, coherency determination and tracking; and
d. curvature/strain analysis.

The azimuth, edge, coherency determination and tracking provides directions and main trends of the slippage passages.

A far-field fracture orientation indicates the direction of stress is determined with acoustic reflection data. Individual dip and azimuth information from these reflectors, e.g., sensors, are made possible with a new 3-dimensional STC processing method, along with ray tracing to provide a confidence factor for each event. The integration with near-wellbore stress indicators (images, calipers) are done to provide a complete integrated workflow.

The curvature/strain analyses provide seismic main trends of the slippage passages and matching these with the BHI data and logs.

Preferably the step of slippage passage calibration comprises one or more of the following steps:
a. PLT (Production Logging Tool), production data build-up time & RFT (Repeat Formation Tester)/MDT (Modular Dynamic Formation Tester) review;
b. well test review;

The PLT, production data build-up time & RFT/MDT review provides calibration points for the 1-dimensional geomechanics model, and pressure matching.

The well test review provides the flow contribution horizons (intervals).

The petrophysical review provides facies descriptions.

The slippage passage potential index (SPPI) is a measure of connectivity along the high porosity zones. It is determined by connectivity of the BHI along the slippage passages.

Preferably, the step of slippage passage prediction comprises the step of creating a 1-dimensional geomechanics model. The 1-dimensional geomechanical model preferably represents one well in terms of slippage passage data. The 1-dimensional geomechanical model identifies the stress regime, elastic and mechanical parameters. It is found that the slippage passages are intensive in the zones of strike slip regime.

Preferably the step of slippage passage characterization comprises one or more of the following steps:
a. creating slippage passage density log and/or slippage passage spacing log for a plurality of wells;
b. slippage passage aperture analysis;
c. estimation of slippage passage density in between of the wells; and
d. geomechanics stress analysis and/or evaluation.

In the step of creating slippage passage density log and/or slippage passage spacing log for a plurality of wells preferably the BHI deliver a porosity image along the slippage passages with porosity determination only from the BHI. Then creating connectivity analysis is preferably performed to indicate the conductivity along the slippage passages and the connectedness, which will be an indication of the permeability.

In the step of slippage passage aperture analysis preferably the porosity distribution and the quantity of secondary porosity fraction can be obtained. The primary assumption for this technique is that the resistivity data from the electrical images is measured in the flushed zone of the borehole. The electrical images are then transformed into a porosity image of the borehole after calibration with external shallow resistivity and log porosity. The following equation is used to get such transformation as described in Akbar, Mahmoud; Chakravorty, Sandeep; Russell, S. Duffy; Al Deeb, Maged A.; Efnik, Mohamed R. Saleh; Thower, Roxy; Karakhanian, Hagop; Mohamed, Sayed Salman; Bushara, Mohamed N. in “Unconventional Approach to Resolving Primary and Secondary Porosity in Gulf Carbonates from Conventional Logs and Borehole Images”; Abu Dhabi International Petroleum Exhibition and Conference, year 2000; SPE-87297-MS,

$${ϕ}_{i} = {{ϕ}_{ext} ( {R}_{ext} * {C}_{i} )}^{1 / m}$$

where ϕi is the derived porosity for each element of the image, ϕext and Rext are the porosity and the shallow resistivity respectively, from conventional logs, Ci is conductivity of each button from the image and m is Archie cementation exponent. An automated analysis of this porosity image, windowed over short intervals (generally 1.2 inch), provides a continuous output of primary and secondary porosity components of the rocks. At every specified sampling rate porosity distribution histograms are computed. The homogeneous reservoir intervals give narrow unimodal distribution. In slippage passages, of the heterogeneous reservoirs, bimodal distribution of porosity is observed. A continuous cutoff is applied to the porosity histograms to separate the contribution of secondary porosity from the matrix fraction. So, the porosity points above the threshold correspond to secondary porosity and those below correspond to the matrix. This will quantify the secondary porosity related to the slippage passages.

In the step of estimation of slippage passage density in between of the wells preferably a comparison of the BHI results and catching the slippage passages intervals showing high connectedness is performed, which provides the lateral extension with the reservoirs. This step preferably needs integration of the BHI geologist with the seismic interpreter. In addition, by creating the 1-dimensional geomechanics models and calculating the elastic parameters (Young's modulus and Poisson Ratio), the elastic parameters of the connected slippage passages intervals are taken into consideration.

In the step of geomechanics stress evaluation preferably on the 1-dimensional geomechanics model the zones of the slippage passages undergoing strike slip are differentiated from the zones of extensional regime. This will highlight the zonation, where the stresses are transferred laterally along the slippage passages. The 1-dimensional geomechanics model deliverables is the vertical stresses and the maximum and minimum horizontal stresses, which indicate the regime.

Preferably, the step of slippage passage parameterization and modelling comprises one or more of the following steps:
a. creating a slippage passage porosity distribution model;
b. creating a slippage passage permeability distribution model; and
c. creating an effective slippage passage permeability distribution model.

The step of creating a slippage passage porosity distribution model preferably uses the results of the step of slippage passage aperture analysis. Further, in this step preferably porosity from isolated pore space, connected pore space, pore space at/connected to slippage passages and porosity from matrix is calculated and evaluated. The BHI image is first transformed into porosity image in similar fashion to the conventional porosity method proposed by (Newberry, Grace, & Stief, 1996), then, the porosity image is associated with the classified heterogeneity image generated to classify the porosity values.

In the step of creating a slippage passage permeability distribution model preferably the calibrated image, dynamic image and the matrix image is used to delineate the heterogeneities.

In the step of creating an effective slippage passage permeability distribution model slippage passages segments are extracted. This step can be carried out separately or combined with automatic picking of slippage passages from previous step to identify the heterogeneity associated with slippage passages and calculate the slippage-associated porosity, especially in cases where the slippage passages are not planar and can't be fully picked. The segment extraction method described in Kherroubi, Josselin, “Automatic extraction of natural fracture traces from borehole images”, in IEEE, 19th International Conference on Pattern Recognition, year 2008 is the preferred technique used to do this. The method, based on mathematical morphology theory, allows to automatically extract separately the low apparent-dip fracture segments and the high-apparent-dip segments. The method produces fast, efficient and repeatable results. Matrix Extraction: In this process, the background of the image, which corresponds to the geological term matrix, is computed by removing non-crossing features on images such as vugs, molds, fracture segments, and slippage passages. The main part of the processing is done by the gray-scale reconstruction transform, as described in Vincent, Luc, “Morphological grayscale reconstruction in image analysis: applications and efficient algorithms” in IEEE, IEEE Transactions on Image Processing, year 1993, 176-201, which removes the features not traversing the image. The matrix image is an essential input in the heterogeneity delineation process and in turn the slippage passages workflow.

Preferably, the steps of creating a slippage passage porosity distribution model; creating a slippage passage permeability distribution model; and creating an effective slippage passage permeability distribution model comprise an upscaling and a 3-dimensional facture intensity modelling.

Preferably, the steps of creating a slippage passage porosity distribution model; creating a slippage passage permeability distribution model; and creating an effective slippage passage permeability distribution model comprise the step of creating a DFN/IFM stochastic slippage passage network. This step preferably comprises identification of the potential flow contributing slippage passages differentiated from the fractures with detailed BHI analysis as described above. Further, this step preferably comprises a prediction of slippage passages intensity, like the fracture intensity between the wells within the reservoir using continuous fracture modeling (CFM) technique. Further, it preferably comprises generating the DFN/IFM (implicit fracture model) with calibration of the fracture/slippage distribution, geometry, trends and calibrating these with the BHI.

Preferably, the step of slippage passage parameterization and modelling comprises the step of creating a 3D MEM and strain map.

Once data is available in terms of many 1-dimensional geomechanics models, a 3-dimensional geomechanics model (or MEM, Mechanical Earth Model) is generated by distributing the geomechanics 3-dimensional model driven by seismic (creating seismic pre-stack inversion to get the elastic parameters), then calibrating these seismic generated elastic parameters with those from the wells (1-dimensional geomechanics models) is performed. This will deliver a 3-dimensional calibrated Geomechanics model, and integrating these with the slippage passages results from the previous steps based on BHI. The 3-dimensional geomechanics model allow forwarding the geomechanics modeling, which will create stress and strain maps. The slippage passages, are zones of high deformation relative to the above and below and therefore accompanying with high strain zonations. This allows to follow the slippage passages laterally away from the wells and allows an optimized well placement for targeting the high production intervals.

Further, the above mentioned problem are solved by using the method of detection of hydrocarbon horizontal slippage passages as described above for positioning a well bore for hydrocarbon production.

The slippage passages are located in areas that are dominated with higher Young's Modulus and maximum horizontal stresses. Therefore, the well location can be planned with different approaches:

### Seismic:

This approach is applicable for the exploration phase when well datasets are limited. Horizons and faults can be interpreted from basic 2-dimensional/3-dimensional seismic interpretation in order to create the structural framework. If strike-slip faults are observed, they will apparently indicate the occurrence of transpressional/transtensional features between the fault segments i.e. higher horizontal stresses. Hence, directional wells should be drilled parallel to the strike-slip faults.

### 3-Dimensional Geomechanics Model:

In the appraisal phase, few wells with log and core data could be available. Then it is possible to conduct a 1-dimensional geomechanics model (MEM: Mechanical Earth Model), on single well then populate the rock properties and create a 3-dimensional geomechanics model using statistical algorithms which provide qualitative predictions of stresses and strains in the reservoir formation.

### Advanced 3-Dimensional Seismic Driven Geomechanics Analysis:

In the development phase, pre-stack 3-dimensional seismic datasets and well data should be available. Then the basic 3-dimensional geomechanics model has to be calibrated with quantitative deliverables from pre-stack seismic inversion such as Vp/Vs, Poisson Ratio, and Young Modulus. With advanced azimuthal inversion, horizontal stresses can be estimated from seismic in order to guide directional drilling and completion (see for a general example that is not related to slippage passage detection, Peake, N., G. Castillo, N. Van de Coevering, S. Voisey, A. Bouziat, K. Chesser, G. Oliver, c. Vinh Ly, and R. Mayer, 2014, Integrating surface seismic, microseismic, rock properties and mineralogy in the Haynesville Shale: Unconventional Resources Technology Conference, 343-353).

### 4. SHORT DESCRIPTION OF THE DRAWINGS

In the following, preferred embodiments of the invention are disclosed by reference to the accompanying figures, in which shows:

FIGS. 1A and 1B a workflow for slippage passage detection and elements of a method of detection of hydrocarbon horizontal slippage passages according to a preferred embodiment;

FIG. 2 an exemplary system for detection of hydrocarbon horizontal slippage passages;

FIG. 3 an exemplary 2-dimensional illustration of results of the method according the invention;

FIG. 4 shows a preferred process of generating a creating a slippage passage permeability distribution model;

FIG. 5 exemplary DFN with seismic attribute images for slippage passages; and

FIG. 6 an exemplary 3-dimensional geomechanics model, showing a slippage passages distribution.

### 5. DETAILED DESCRIPTION OF PREFERRED EMBODIMENTS

In the following, preferred embodiments of the invention are described in detail with respect to the figures.

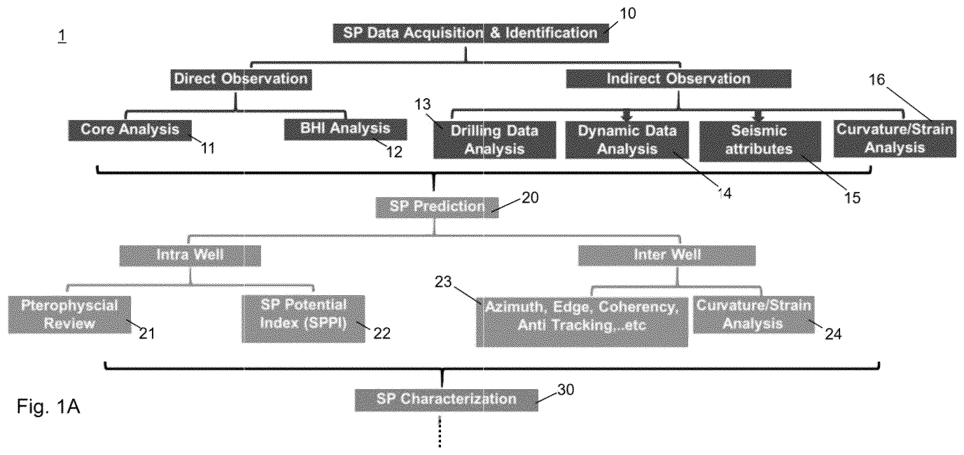

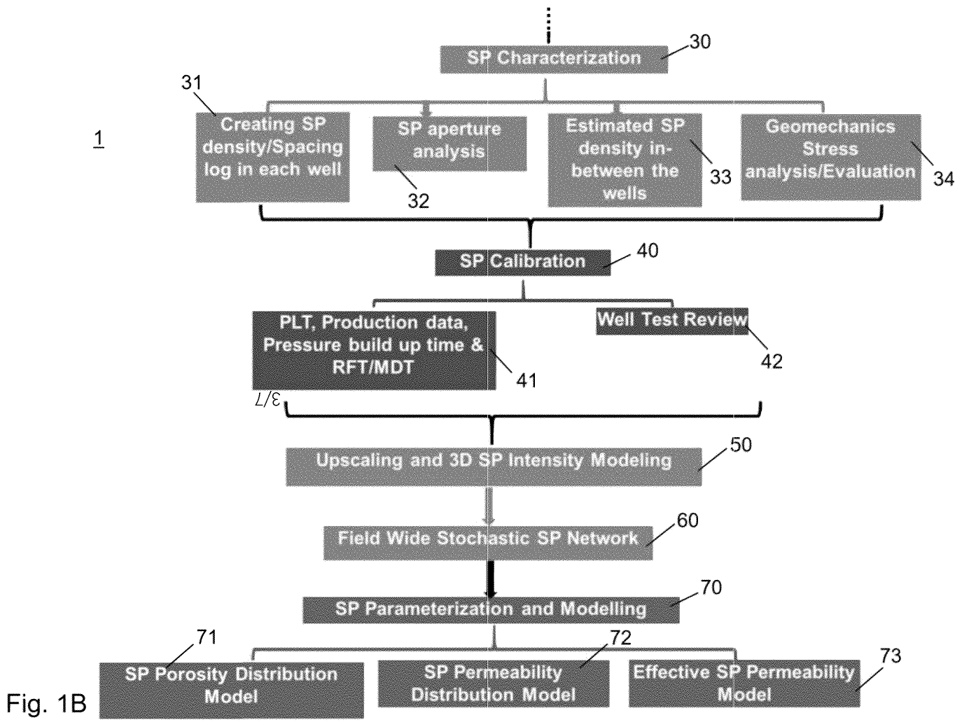

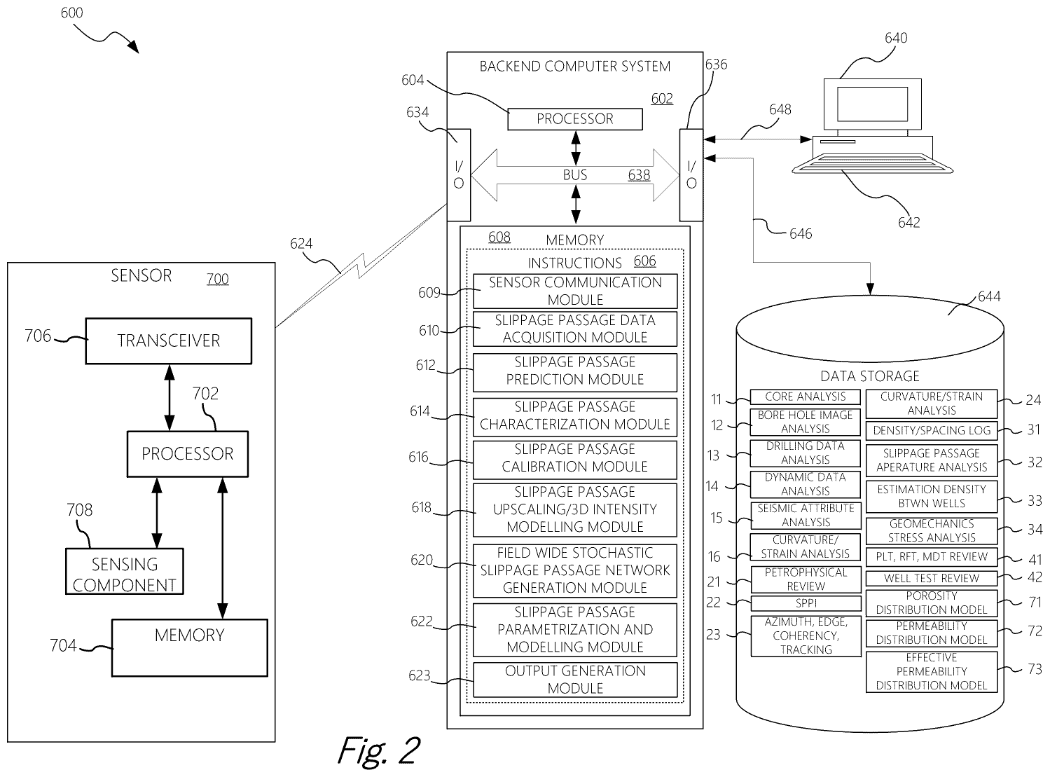

FIGS. 1A and 1B seen together show a workflow 1 for slippage passage detection and elements of a method of detection of hydrocarbon horizontal slippage passages according to a preferred embodiment. The workflow 1 comprises the main steps of slippage passage data acquisition and identification 10, slippage passage prediction 20, slippage passage characterization 30, and slippage passage parameterization and modelling 70. In accordance with some embodiments, some or all of the workflow 1 may be performed by an application-specific computer system 602, hereinafter referenced as “backend computer system 602” as shown in FIG. 2. Operations of the workflow 1 in FIGS. 1A and 1B will be better understood in conjunction with the system for detection of hydrocarbon horizontal slippage passages 600 shown in FIG. 2.

As shown in FIG. 2, the system 600 includes one or more sensors 700 in data communication with the backend computer system 602 via direct or indirect (e.g., distributed) communications mechanisms. The backend computer system 602 may be configured to interact with a plurality of different devices and components, as are illustrated therein. The exemplary backend computer system 602 includes a processor 604, which performs the exemplary method by execution of processing instructions 606 that are stored in memory 608 connected to the processor 604, as well as controlling the overall operation of the computer system 602.

The instructions 606 may include a sensor communication module 609 configured to establish uni- or bi-directional communications with one or more sensors 700 deployed, emplaced, or otherwise associated with a hydrocarbon deposit, a well, a geological formation, or the like. In some embodiments, the sensor communication module 609 may be configured to communicate with a dispersed net or array of sensors 700 covering a large geographical area. In other embodiments, the sensor communication module 609 may be configured to send instructions to perform one or more operations by the sensors 700 to collect and/or transmit collected data to the backend computer system 602. The sensor communication module 609 may also be configured to communicate with disparate databases (not shown) containing pre-acquired geological information obtained from third-party sensors and incorporate such data into the processing of the method 1 described herein.

The instructions 606 stored in memory 608 may include a slippage passage acquisition module 610 configured to acquire and perform slippage data acquisition 10. The step of slippage passage data acquisition 10 can be performed by the slippage passage acquisition module 610 via direct observation of well data or indirect observation of data of the surrounding of the well collected from one or more sensors 700 positioned in relative proximity to at least one well or an area surrounding the well. In accordance with one or more embodiments disclosed and contemplated herein, the sensors 700 may comprise, for example and without limitation, seismological sensors, radiation sensors, sonic or ultrasonic sensors, ground-penetrating RADAR sensors, electromagnetic radiation sensors, LIDAR sensors, reflectometry sensors, optical sensors, infrared sensors, spectrometers, radiometers, scatterometers, altimetric sensors, shuttle radar topography mission sensors, interferometric sensors, acoustic sensors, digital sensors, analog sensors, or any other type of active or passive sensors configured for geological analytical purposes, as will be understood. The one or more sensors 700 may be communicatively coupled to a backend computer system 602 for sending and receiving data therebetween.

The slippage passage data acquisition module 610 may further be configured to perform one or more additional operations on data received from the one or more sensors 700, including one or more of the following steps:
a. core analysis 11;
b. bore hole image analysis 12;
c. drilling data analysis 13;
d. dynamic data analysis 14;
e. seismic attribute analysis 15; and
f. curvature/strain analysis 16.

The slippage passage data acquisition module 610 may utilize one or more algorithms, machine-learning processes, artificial intelligence components, etc., in acquiring and analyzing data. Suitable methods, systems, and algorithms for core analysis 11, bore hole image analysis 12, drilling data analysis 13, dynamic data analysis 14 et seq., are provided in U.S. patent application Ser. No. 18/000,596 filed Dec. 2, 2022, and published as U.S. Patent Application Publication No. 2023/0332495 on Oct. 19, 2023, titled BOREHOLE IMAGE INTERPRETATION AND ANALYSIS, the entire disclosure of which is incorporated by reference herein.

As illustrated in FIG. 2, the instructions 606 may also include a slippage passage prediction module 612 configured to perform the step of slippage passage prediction 20, shown in FIGS. 1A and 1B. The slippage passage prediction 20 implemented by the slippage passage prediction module 612 can be performed intra well for one specific well or inter well, regarding the relationships of a plurality of wells. In performing the slippage passage prediction 20, the slippage passage prediction module 612 may further comprise one or more of the following steps:
a. petrophysical review 21;
d. determining of slippage passage potential index (SPPI) 22;
e. azimuth, edge, coherency determination and tracking 23; and
f. curvature/strain analyses 24.

The instructions 606 stored in memory 608 may further include a slippage passage characterization module 614 configured to perform the step of slippage passage characterization 30. In performing the step of slippage passage characterization 30, the slippage passage characterization module 614 may also perform one or more of the following steps:
a. creating slippage passage density log and/or slippage passage spacing log for a plurality of wells 31;
b. slippage passage aperture analysis 32;
c. estimation of slippage passage density in between of the wells 33; and
d. geomechanics stress analysis and/or evaluation 34.

As shown in FIG. 2, the instructions 606 may further include a slippage passage calibration module 616 configured to perform the step of slippage passage calibration 40. In accordance with some embodiments, the slippage passage calibration module 616 may also perform one or more of the following steps:
a. PLT (Production Logging Tool), production data build-up time & RFT (Repeat Formation Tester)/MDT (Modular Dynamic Formation Tester) review 41; and
b. well test review 42.

The instructions 606 also comprise a slippage passage upscaling/3D intensity modelling module 618 configured to perform the step of slippage passage upscaling and 3-dimensional slippage passage intensity modeling 50.

The memory 608 may also include instructions 606 that comprise a field wide stochastic slippage passage network generation module 620. In accordance with some embodiments, the field wide stochastic slippage passage network generation module 620 may be configured to perform the step of generating a field wide stochastic slippage passage network 60.

In addition, the instructions 606 may include a slippage passage parameterization and modelling module 622 configured to perform the step of slippage passage parametrization and modelling 70. The step of slippage passage parametrization and modelling 70 performed by the parametrization and modelling module 622 may include one or more of the following steps:
a. creating a slippage passage porosity distribution model 71;
b. creating a slippage passage permeability distribution model 72; and
c. creating an effective slippage passage permeability distribution model 73.

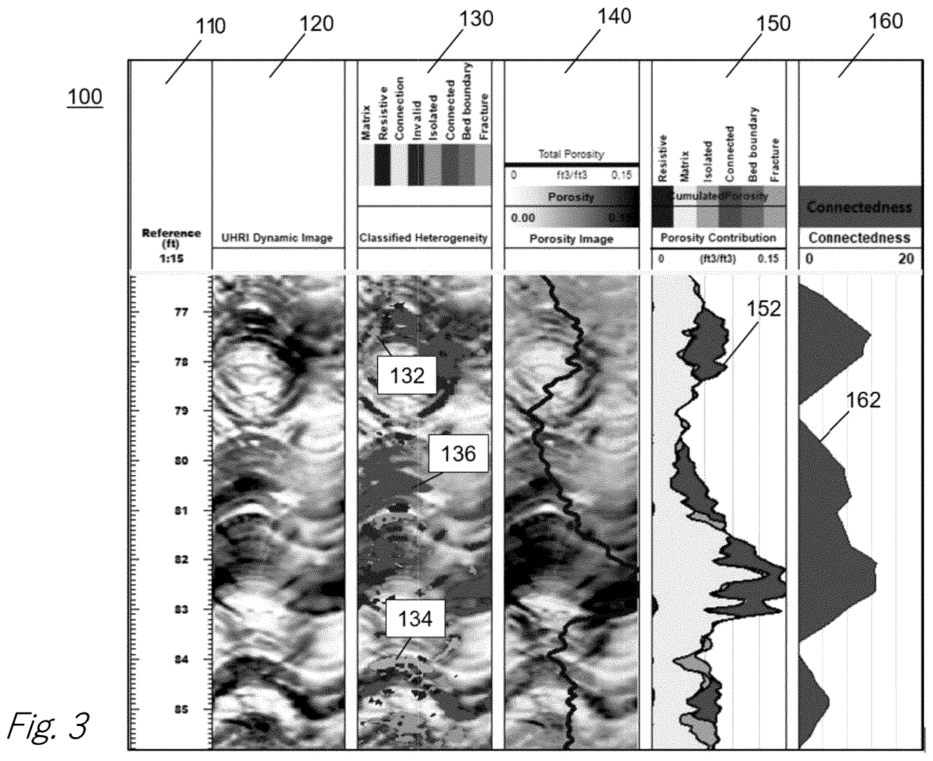

The instructions 606 may further include an output generation module 623 configured to generate at least one of a visual or auditory output via the display 640 or other associated device. In some embodiments, the display 640 may be configured to generate a graphical user interface for displaying one or three-dimensional images representing the slippage passage information, models, etc., calculated and generated in accordance with the method 1 described herein. In other embodiments, the output generation module 623 is configured to output a report, graphics, animation, images, or the like, in accordance with the outputs of the various modules 610-622, as illustrated in FIGS. 3-6, discussed below. In varying other embodiments, the output generation module 623 may be configured to automatically identify predesignated features of the slippage passage corresponding to viable hydrocarbon locations and send an electronic communication to a specified device, generate an alert, or the like.

The various components of the backend computer system 602 may all be connected by a data/control bus 638. The processor 604 of the backend computer system 602 is in communication with an associated data storage 644 via a link 646. A suitable communications link 646 may include, for example, the public switched telephone network, a proprietary communications network, infrared, optical, or other suitable wired or wireless data communications. The data storage 644 is capable of implementation on components of the backend computer system 602, e.g., stored in local memory 608, i.e., on hard drives, virtual drives, or the like, or on remote memory accessible to the backend computer system 602.

The associated data storage 644 corresponds to any organized collections of data used for one or more purposes. In some embodiments, the associated data storage 644 may store the output of the various modules 610-622 during final and/or intermediate performance of the steps set forth in the workflow 1 of FIGS. 1A and 1B. For example, and without limitation, the associated data storage 644 may store data related to core analysis 11, bore hole analysis 12, drilling data analysis 13, dynamic data analysis 14, seismic attribute analysis 15, curvature/strain analysis 16, petrophysical review 21, SPPI 22, azimuth/edge/coherency, tracking 23, curvature/strain analysis 24, density/spacing log(s) 31, slippage passage aperture analysis 32, estimation density between wells 33, geomechanics stress analysis 34, PLT/RFT/MDT review 41, porosity distribution model 71, permeability distribution model 72, effective permeability distribution model 73, raw sensor data, processed sensor data, or the like. Implementation of the associated data storage 644 is capable of occurring on any mass storage device(s), for example, magnetic storage drives, a hard disk drive, optical storage devices, flash memory devices, or a suitable combination thereof. The associated data storage 644 may be implemented as a component of the backend computer system 602, e.g., resident in memory 608, or the like.

The backend computer system 602 may include one or more input/output (I/O) interface devices 634 and 636 for communicating with external devices. The I/O interface 634 may communicate, via communications link 648, with one or more of a display device 640, for displaying information, such estimated destinations, and a user input device 642, such as a keyboard or touch or writable screen, for inputting text, and/or a cursor control device, such as mouse, trackball, or the like, for communicating user input information and command selections to the processor 604.

It will be appreciated that the hydrocarbon horizontal slippage passage detection system 600 is capable of implementation using a distributed computing environment, such as a computer network, which is representative of any distributed communications system capable of enabling the exchange of data between two or more electronic devices. It will be further appreciated that such a computer network includes, for example and without limitation, a virtual local area network, a wide area network, a personal area network, a local area network, the Internet, an intranet, or any suitable combination thereof. Accordingly, such a computer network comprises physical layers and transport layers, as illustrated by various conventional data transport mechanisms, such as, for example and without limitation, Token-Ring, Ethernet, or other wireless or wire-based data communication mechanisms.

Furthermore, while depicted in FIG. 2 as a networked set of components, the system and method are capable of implementation on a stand-alone device adapted to perform the methods described herein.

The backend computer system 602 may comprise a special purpose computer constructed from various components to include the modules 610-623 described above. In alternate embodiments, the backend computer 602 may be implemented on a computer server, workstation, personal computer, cellular telephone, tablet computer, pager, combination thereof, or other computing device capable of executing instructions for performing the exemplary method.

According to one example embodiment, the backend computer system 602 includes hardware, software, and/or any suitable combination thereof, configured to interact with an associated user, a networked device, networked storage, remote devices, or the like.

The memory 608 may represent any type of non-transitory computer readable medium such as random access memory (RAM), read only memory (ROM), magnetic disk or tape, optical disk, flash memory, or holographic memory. In one embodiment, the memory 608 comprises a combination of random access memory and read only memory. In some embodiments, the processor 604 and memory 608 may be combined in a single chip. The network interface(s) 634, 636 allow the computer to communicate with other devices via a computer network, and may comprise a modulator/demodulator (MODEM). Memory 608 may store data the processed in the method as well as the instructions for performing the exemplary method.

The digital processor 604 can be variously embodied, such as by a single core processor, a dual core processor (or more generally by a multiple core processor), a digital processor and cooperating math coprocessor, a digital controller, or the like. The digital processor 604, in addition to controlling the operation of the server computer 602, executes the instructions 606 stored in memory 608 for performing one or more methods described herein.

The system 600 depicted in FIG. 2 may include one or more sensors 700, positioned adjacent to, within, around, or otherwise associated with one or more wells, fractures, geographic features, etc., configured to sense a variety of measurements (or the like) and communicate the same to the backend computer system 602. In some embodiments, one or more sensors 700 may be implemented in a satellite, an airborne asset (e.g., plane, drone, helicopter, etc.), or other remote location. As noted above, suitable examples of such sensors 700 may include, for example and without limitation: seismological sensors, radiation sensors, sonic or ultrasonic sensors, ground-penetrating RADAR sensors, electromagnetic radiation sensors, LIDAR sensors, reflectometry sensors, optical sensors, infrared sensors, spectrometers, radiometers, scatterometers, altimetric sensors, shuttle radar topography mission sensors, interferometric sensors, digital sensors, analog sensors, or any other type of active or passive sensors configured for geological analytical purposes.

As shown in FIG. 2, the sensor 700 may be in communication with the backend computer system 602 via a data communications link 624. The data communications link 624 between the sensor(s) 700 and the backend computer system 602 may be accomplished via any suitable channel of data communications such as wireless communications, for example Bluetooth, WiMax, 802.11a, 802.11b, 802.11g, 802.11 (x), a proprietary communications network, infrared, optical, the public switched telephone network, or any suitable wireless data transmission system, or wired communications.

In one embodiment, the sensor(s) 700 may communicate with the backend computer system 602 via the Internet.

The sensor 700 may include a processor 702, which executes one or more instructions in the performance of an exemplary method disclosed herein. The sensor 700 may further include a memory 704 storing the instructions in data communication with the processor 702. The processor 702 of the sensor 700 may be in data communication with the backend computer system 702 via a transceiver 706. As shown in FIG. 2, the sensor 700 further includes one or more sensing components 708, configured to send and/or receive signals in accordance with its corresponding type of sensor, e.g., emit/receive RADAR/LIDAR, EM radiation, optical images, etc. The transceiver 706 may be configured to send data from the sensing component 708 to the backend computer system 602.

As illustrated in FIG. 2, the memory 704 may represent any type of non-transitory computer readable medium such as random access memory (RAM), read only memory (ROM), magnetic disk or tape, optical disk, flash memory, or holographic memory. In one embodiment, the memory 704 comprises a combination of random access memory and read only memory. In some embodiments, the processor 702 and memory 704 may be combined in a single chip. The transceiver 706 allows the sensor 700 to communicate with other devices via a communications network, and may comprise a modulator/demodulator (MODEM). The memory 704 may store data the processed in the method as well as the instructions for performing the exemplary method. The digital processor 702 can be variously embodied, such as by a single core processor, a dual core processor (or more generally by a multiple core processor), a digital processor and cooperating math coprocessor, a digital controller, or the like.

FIG. 3 shows an exemplary 2-dimensional illustration 100 of results of the method 1 implemented in accordance with the system 600 shown in FIG. 2. In track 110 the reference depth of the formation under investigation is provided. Track 120 shows a UHRI dynamic image of the formation. Track 130 shows a classified heterogeneity image and track 140 a porosity image generated from calibrated UHRI image and total porosity log. Track 150 shows a porosity contribution per texture class using porosity image 140 and the classified heterogeneity image 130. Track 160 shows a connectedness curve generated for connected porosity. In the classified heterogeneity image 130 isolated porosity 132 and fracture connected porosity 134 is shown together with connected porosity 136.

In accordance with some embodiments, the slippage passage parametrization and modelling module 622 may perform the step of creating a slippage passage porosity distribution model 71 using the results of the step of slippage passage aperture analysis 32 performed by the slippage passage characterization module 614. For example, as shown in FIG. 3 a value in the porosity image 120 which is at a connected conductive spot in the heterogeneity image 130 is classified as porosity from connected conductive spot. Two types of curves are created for each heterogeneity class. The first curve 152 is the contribution of each texture category to the total image porosity, the second one 162 is the average porosity of each texture class. The textural and porosity analysis in reservoir revealed varying amount of heterogeneity in form of conductive and resistive (dense) areas across the whole interval. The conductive heterogeneities are due to porous areas (patches of intergranular and intercrystalline porosity, mouldic, vuggy porosity and slippage passages conductive intervals) of different size, shape and conductivity. The resistive heterogeneities are due to dense cemented areas of lower or zero porosity. The extracted quantitative information from BHI was used to identify several heterogeneous zones associated with higher secondary porosity and higher connectedness zones, most of the connected porosity zones were found in two units of FIG. 3 showing one example. Track 150 shows the image extracted porosity type contributions to total porosity. The shading in track 150 indicates the contribution from each pore type. The quantitative information on the different pore types 152 and the pore connectedness index 162 is very useful for identifying the most productive zones in reservoir and to understand the correlations between various reservoir porosity components and well productivity data.

In this exemplary well of FIG. 3, a PLT survey was carried out to define the production profile. Good production contribution has been obtained from intervals where standard logs show low porosity whereas the slippage passages zones having higher porosity and responsible for the main production. Excellent correlation, however, is observed between production log profile and the connectedness log 160 derived from the borehole image 120. It is inferred that the variation in production profile is triggered by the slippage passage variation in the reservoir, i.e. zones dominated by connected slippage passages yield higher production rate whereas less rates are observed in zones dominated by other zones. Zones dominated by isolated vuggy porosity and matrix porosity have little to no contribution to production. The pore connectedness index 160 provides a significant and relevant qualitative measure to predict the producibility and can be used to optimize the completion in future wells.

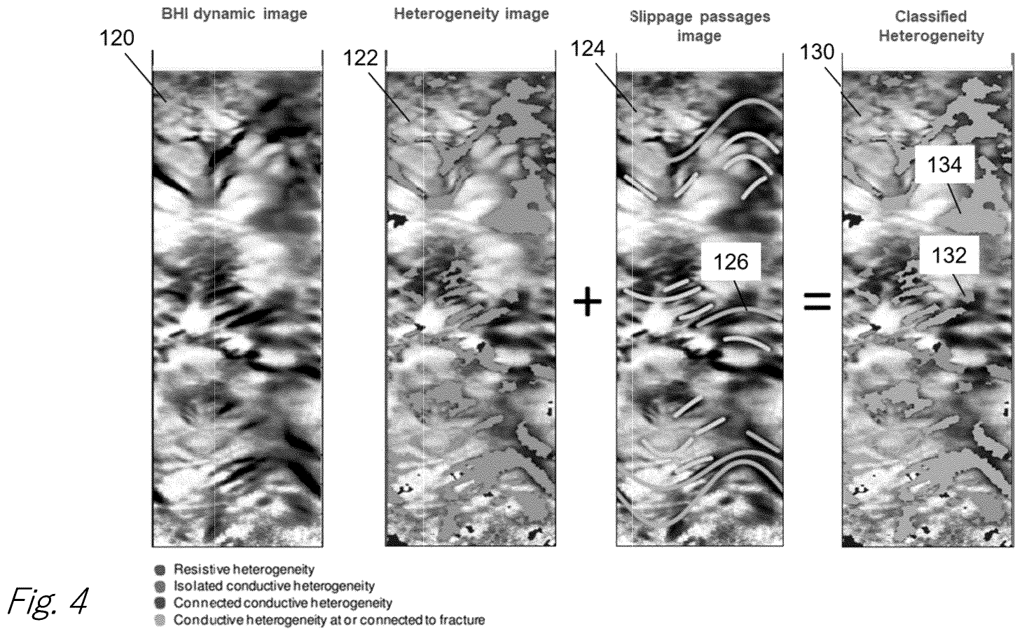

FIG. 4 shows the process of generating a creating a slippage passage permeability distribution model 72 by the slippage passage parametrization and modelling module 622 via an example of conductive heterogeneity sub-classified into fracture connected heterogeneity. The first track shows the BHI dynamic image 120. The second track shows a conductive heterogeneity image 122. The third track shows a slippage passage image 124 with fracture sinusoids 126 that have been previously picked or extracted using segment extraction methods. The fourth track shows the subcategorized heterogeneity image 130 using fracture dips conductive heterogeneity at or connected to fractures 134 (orange) and into isolated conductive heterogeneity 132 (green).

In the step of creating a slippage passage permeability distribution model 72, the slippage passage parametrization and modelling module 622, preferably the calibrated image, dynamic image 120 and the matrix image is used to delineate the heterogeneities. The entire image is first segmented into mosaic pieces (segments) using a well-known image segmentation method called watershed transform method as explained in Meyer, F.; Beucher, S., “Morphological segmentation” in “Journal of Visual Communication and Image Representation”, year 1990, pages 21-46. Each mosaic piece is characterized by its attributes such as the peak/valley value, contrast against matrix image, size, and type. Two mosaic types are extracted: conductive type (the mosaic pieces above matrix image) and resistive type (the mosaic pieces below matrix image). To examine the connectedness between conductive mosaic pieces, crest lines are extracted by applying the watershed transform to the original image. The crest line of the image helps identify the isolated and connected conductive features. A cut-off value is applied then on the mosaic pieces attributes (value and contrast) to extract the conductive heterogeneities (e.g. slippage passages) and the resistive heterogeneities (e.g. cemented patches). The extracted conductive heterogeneity spots 122 are subclassified into different categories 132, 235, 136. Spots connected by crest lines to another spot are classified as connected spots 136. The spots connected to slippage passages (previously extracted slippage traces and dips) are classified as slippage passages spots 126, which are the spots aligned along slippage passages are classified, and the rest are classified as isolated conductive spots 132. Size, contrast, and surface proportion of each spot/heterogeneity category are computed and represented as curves. The connectedness (is compatible to permeability) curve 162 is extracted, and it is defined by the average of the differences in conductivity between matrix and crest line (zero if there is no line) at each depth level. This curve is a very good indicator for productive zones. It is also possible here to exclude the conductive spots related to clay layers, stylolites, induced fractures and borehole breakouts using the relevant dips previously picked, such spots are classified as false porosity and it will be excluded from the porosity calculations.

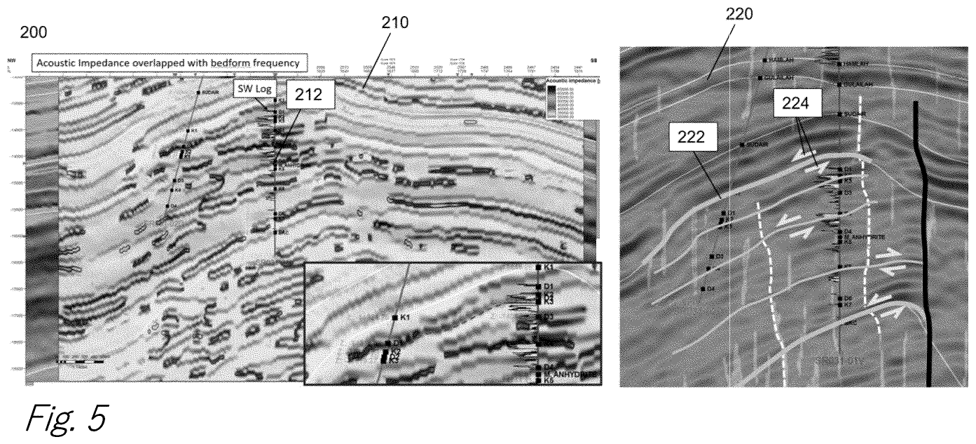

FIG. 5 shows a field wide stochastic slippage passage Network 60 generated by the field wide stochastic slippage passage network generation module 620 in accordance with some embodiments of the present disclosure. The acoustic impedance overlapped with bedform frequency 200 comprises on the left side the seismic attribute image 210 for slippage passages and to the right a seismic image 220 with slippage passages 222 and arrows 224 indicating slippage directions along the horizons. Generally, a stochastic slippage network model 210 is created as a basic step as attribute, along with creating the slippage passages interpretation 220 and comparing both. Then comparing the results from the BHI with the flow directions 224 of the stochastic slippage passage network 200 and those attributes related to the slippages passages 222 attributes.

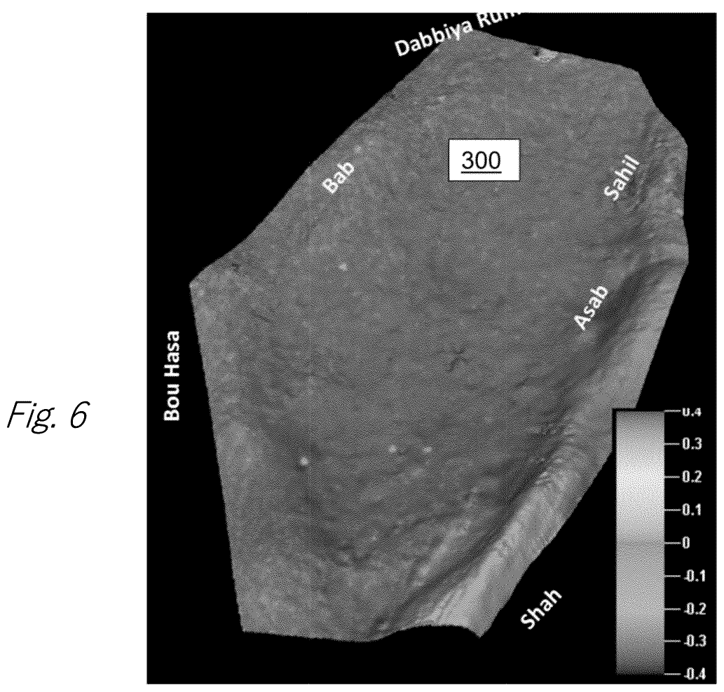

FIG. 6 shows an exemplary 3-dimensional geomechanics model (MEM) with a strain map 300 obtained by a step 50 of creating a 3-dimensional MEM and strain map 300 generated by the slippage passage upscaling/3-dimensional intensity modelling module 618. The upscaled and extrapolated locations of extreme values of shear stress indicate the presence of potential slippage passages.

The term “software,” as used herein, is intended to encompass any collection or set of instructions executable by a computer or other digital system so as to configure the computer or other digital system to perform the task that is the intent of the software. The term “software” as used herein is intended to encompass such instructions stored in storage medium such as RAM, a hard disk, optical disk, or so forth, and is also intended to encompass so-called “firmware” that is software stored on a ROM or so forth. Such software may be organized in various ways, and may include software components organized as libraries, Internet-based programs stored on a remote server or so forth, source code, interpretive code, object code, directly executable code, and so forth. It is contemplated that the software may invoke system-level code or calls to other software residing on a server or other location to perform certain functions.

Some portions of the detailed description herein are presented in terms of algorithms and symbolic representations of operations on data bits performed by conventional computer components, including a central processing unit (CPU), memory storage devices for the CPU, and connected display devices. These algorithmic descriptions and representations are the means used by those skilled in the data processing arts to most effectively convey the substance of their work to others skilled in the art. An algorithm is generally perceived as a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be understood, however, that all of these and similar terms are to be associated with the appropriate physical quantities and are merely convenient labels applied to these quantities. Unless specifically stated otherwise, as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

The exemplary embodiment also relates to an apparatus for performing the operations discussed herein. This apparatus may be specially constructed for the required purposes, or it may comprise a general-purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, and each coupled to a computer system bus.

The algorithms and displays presented herein are not inherently related to any particular computer or other apparatus. Various general-purpose systems may be used with programs in accordance with the teachings herein, or it may prove convenient to construct more specialized apparatus to perform the methods described herein. The structure for a variety of these systems is apparent from the description above. In addition, the exemplary embodiment is not described with reference to any particular programming language. It will be appreciated that a variety of programming languages may be used to implement the teachings of the exemplary embodiment as described herein.

A machine-readable medium includes any mechanism for storing or transmitting information in a form readable by a machine (e.g., a computer). For instance, a machine-readable medium includes read only memory (“ROM”); random access memory (“RAM”); magnetic disk storage media; optical storage media; flash memory devices; and electrical, optical, acoustical or other form of propagated signals (e.g., carrier waves, infrared signals, digital signals, etc.), just to mention a few examples. The methods illustrated throughout the specification, may be implemented in a computer program product that may be executed on a computer. The computer program product may comprise a non-transitory computer-readable recording medium on which a control program is recorded, such as a disk, hard drive, or the like. Common forms of non-transitory computer-readable media include, for example, floppy disks, flexible disks, hard disks, magnetic tape, or any other magnetic storage medium, CD-ROM, DVD, or any other optical medium, a RAM, a PROM, an EPROM, a FLASH-EPROM, or other memory chip or cartridge, or any other tangible medium from which a computer can read and use.

Alternatively, the method may be implemented in transitory media, such as a transmittable carrier wave in which the control program is embodied as a data signal using transmission media, such as acoustic or light waves, such as those generated during radio wave and infrared data communications, and the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Accordingly, various presently unforeseen or unanticipated alternatives, modifications, variations or improvements therein may be subsequently made by those skilled in the art which are also intended to be encompassed by the following claims.

1. A computer-implemented method of detecting hydrocarbon horizontal slippage passages, using a computer system comprising at least one processor in communication with memory, the method comprising:
a. acquiring and identifying slippage passage data by the processor, wherein the data acquisition and identification includes identifying a slippage passage as being one or more naturally occurring macroscopic planar discontinuities in rock due to deformation and/or diagenesis, and wherein the slippage passage data is acquired from at least one sensor;
b. predicting the slippage passage based on computational analysis of the acquired and identified slippage passage data by the processor;
c. generating slippage passage characterization data based upon computational analysis of the predicted slippage passage by the processor;
d. calibrating the slippage passage data by the processor in accordance with the prediction and characterization data;
e. parameterizing and modelling at least one slippage passage by generating one or more 3-dimensional models of the at least one slippage passage; and
f. displaying the one or more 3-dimensional models of the at least one slippage passage.

2. The computer-implemented method according to claim 1, wherein the step of slippage passage data acquisition and identification comprises data acquisition in stratified rock.

3. The computer-implemented method according to claim 1, wherein the step of slippage passage data acquisition and identification comprises acquiring borehole image data.

4. The computer-implemented method according to claim 1, wherein the step of slippage passage data acquisition and identification comprises an acquisition of one or more of:
a. density data;
b. gamma ray data;
c. sonic compressional data;
d. fast sonic shear data;
e. slow sonic shear data; and
f. core data.

5. The computer-implemented method according to claim 1, wherein the step of slippage data acquisition and identification comprises one or more of the following steps:
a. core analysis;
b. bore hole image analysis;
c. drilling data analysis;
d. dynamic data analysis;
e. seismic attribute analysis; and
f. curvature/strain analysis.

6. The computer-implemented method according to claim 1, wherein the step of slippage passage prediction comprises one or more of the following steps:
a. petrophysical review;
b. determining of slippage passage potential index (SPPI);
c. azimuth, edge, coherency determination and tracking; and
d. curvature/strain analysis.

7. The computer-implemented method according to claim 1 wherein the step of slippage passage prediction comprises the step of creating a one-dimensional geomechanics model.

8. The computer-implemented method according to claim 1; wherein the step of slippage passage characterization comprises one or more of the following steps:
a. creating slippage passage density log and/or slippage passage spacing log for a plurality of wells;
b. slippage passage aperture analysis;
c. estimation of slippage passage density in-between the wells; and
d. geomechanics stress analysis and/or evaluation.

9. The computer-implemented method according to claim 1, wherein the step of slippage passage calibration comprises one or more of the following steps:
a. PLT, production data build-up time & RFT/MDT review; or
b. well test review.

10. The computer-implemented method according to claim 1, further comprising the step of slippage passage upscaling and 3-dimensional slippage passage intensity modeling.

11. The computer-implemented method according to claim 1, further comprising the step of generating a slippage passage field wide stochastic slippage passage network.

12. The computer-implemented method according to claim 1, wherein the step of slippage passage parameterization and modelling comprises one or more of the following steps:
a. creating a slippage passage porosity distribution model;
b. creating a slippage passage permeability distribution model; and
c. creating an effective slippage passage permeability distribution model.

13. The computer-implemented method according to claim 1, wherein the wherein the step of slippage passage parameterization and modelling comprises the step of creating a 3-dimensional MEM and strain map.

14. Use of the computer-implemented method of detection of hydrocarbon horizontal slippage passages according to claim 1 for positioning a well bore for hydrocarbon production.

15. The computer-implemented method according to claim 1, wherein the step of slippage passage data acquisition and identification includes at least generating and displaying a borehole image.

16. The computer-implemented method according to claim 1, wherein the step of slippage passage prediction includes generating and storing at least one 1-dimensional geomechanics model of a well.

17. The computer-implemented method according to claim 1, wherein the step of slippage passage data acquisition and identification includes measuring a borehole with a sonic tool to determine stress regime and direction.

18. The computer-implemented method according to claim 1, further including the step of locating horizontal slippage passages that contain retrievable oil and gas deposits.

19. A system for detecting hydrocarbon horizontal slippage passages, comprising:
at least one sensor associated with at least one well;
a computer in communication with the at least one sensor, the computer comprising a processor in communication with memory storing instructions which are executed by the processor causing the processor to:
receive slippage passage data from the at least one sensor;
acquire and identify slippage passage data, wherein the data acquisition and identification includes identifying a slippage passage as being one or more naturally occurring macroscopic planar discontinuities in rock due to deformation and/or diagenesis;
predict the slippage passage based on computational analysis of the acquired and identified slippage passage data;
generate slippage passage characterization data based upon computational analysis of the predicted slippage passage;
calibrate the slippage passage data in accordance with the prediction and characterization data;
parameterize and model at least one slippage passage by generating one or more 3-dimensional models of the at least one slippage passage; and
display the one or more 3-dimensional models of the at least one slippage passage on an associated display.
